(19) United States
(12) Patent Application Publication
(10) Pub. No.: US 2024/0413039 A1
(43) Pub. Date: Dec. 12, 2024

(54) HEAT SINK FOR STACKED MULTI-GATE DEVICE

(71) Applicant: Taiwan Semiconductor Manufacturing Company, Ltd., Hsinchu (TW)

(72) Inventors: Che Chi Shih, Taoyuan City (TW); Wei-Yen Woon, Taoyuan City (TW); Ku-Feng Yang, Hsinchu County (TW); Szuya Liao, Hsinchu (TW)

(21) Appl. No.: 18/463,062

(22) Filed: Sep. 7, 2023

Related U.S. Application Data
(60) Provisional application No. 63/506,859, filed on Jun. 8, 2023.

(51) Int. Cl. H01L 23/367; H01L 21/8238; H01L 27/092; H01L 29/06; H01L 29/08; H01L 29/423; H01L 29/66; H01L 29/775; H01L 29/786

(52) U.S. Cl. CPC H01L 23/367; H01L 21/823807; H01L 21/823814; H01L 27/092; H01L 29/0673; H01L 29/0847; H01L 29/42392; H01L 29/66439; H01L 29/66545; H01L 29/775; H01L 29/78696

(57) ABSTRACT

Semiconductor structures and methods are provided. A semiconductor structure according to the present disclosure includes a semiconductor substrate, a high-Kappa dielectric layer disposed on the semiconductor substrate, a first plurality of nanostructures disposed over the high-Kappa dielectric layer, a middle dielectric layer disposed over the first plurality of nanostructures, a second plurality of nanostructures over the middle dielectric layer, a first gate structure wrapping around the first plurality of nanostructures, a second gate structure wrapping around the second plurality of nanostructures. The high-Kappa dielectric layer includes metal nitride, metal oxide, silicon carbide, graphene, or diamond.

### PRIORITY DATA

This application claims priority to U.S. Provisional Patent Application No. 63/506,859, filed on Jun. 8, 2023, which is hereby incorporated herein by reference in its entirety.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

For example, as integrated circuit (IC) technologies progress towards smaller technology nodes, multi-gate devices have been introduced to improve gate control by increasing gate-channel coupling, reducing off-state current, and reducing short-channel effects (SCEs). A multi-gate device generally refers to a device having a gate structure, or portion thereof, disposed over more than one side of a channel region. Fin-like field effect transistors (FinFETs) and multi-bridge-channel (MBC) transistors are examples of multi-gate devices that have become popular and promising candidates for high performance and low leakage applications. A FinFET has an elevated channel wrapped by a gate on more than one side (for example, the gate wraps a top and sidewalls of a “fin” of semiconductor material extending from a substrate). An MBC transistor has a gate structure that can extend, partially or fully, around a channel region to provide access to the channel region on two or more sides. Because its gate structure surrounds the channel regions, an MBC transistor may also be referred to as a surrounding gate transistor (SGT) or a gate-all-around (GAA) transistor. The channel region of an MBC transistor may be formed from nanowires, nanosheets, other nanostructures, and/or other suitable structures. The shapes of the channel region have also given an MBC transistor alternative names such as a nanosheet transistor or a nanowire transistor.

As the semiconductor industry further progresses into advanced technology process nodes in pursuit of higher device density, higher performance, and lower costs, challenges from both fabrication and design issues have led to stacked device structure configurations, such as complementary field effect transistors (C-FET) where multi-gate transistors are stacked vertically, one over the other.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 illustrates a flow chart of a method for forming a semiconductor device having a vertical C-FET structure, according to one or more aspects of the present disclosure.

FIGS. 2-11 illustrate fragmentary cross-sectional views of a workpiece undergoing various fabrication processes in the method of FIG. 1, according to one or more aspects of the present disclosure.

FIG. 12 illustrates a flow chart of a method for forming a semiconductor device having a vertical C-FET structure, according to one or more aspects of the present disclosure.

FIGS. 13-24 illustrate fragmentary cross-sectional views of a workpiece undergoing various fabrication processes in the method of FIG. 12, according to one or more aspects of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Spatially relative terms, such as “beneath,” “below.” “lower.” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.25 nm to 5.75 nm where manufacturing tolerances associated with depositing the material layer are known to be +/−15% by one of ordinary skill in the art.

A stacked multi-gate device refers to a semiconductor device that includes a bottom multi-gate device and a top multi-gate device stacked over the bottom multi-gate device. When the bottom multi-gate device and the top multi-gate device are of different conductivity types, the stacked multi-gate device may be a complementary field effect transistor (C-FET). The multi-gate devices in a C-FET may be FinFETs or GAA transistors. Due to limited routing areas, routing for a C-FET is accomplished with both a frontside interconnect structure and a backside interconnect structure. The process to form the backside interconnect structure usually involves removal of the semiconductor substrate, which serves as a heat sink. Compared to multi-gate devices, stacked multi-gate devices tend generate more heat. The additional heat, compounded with the lack of a heat sink, poses challenges in heat dissipation for multi-gate devices.

The present disclosure provides methods to introduce one or more high thermal conductivity (high-Kappa) layers in a C-FET structure to serve as a heat sink. In one example process, two high-Kappa layers are applied as bonding layers to bond two semiconductor stacks together to form a superlattice structure. The superlattice structure is patterned to form fin-shaped structures to undergo further processes to form C-FET structures and the two high-Kappa layers are disposed between a bottom multi-gate device and a top multi-gate device. In another example process, a superlattice structure is formed on a first substrate. A high-Kappa dielectric layer is then deposited over the superlattice structure. After a semiconductor layer is deposited over the high-Kappa dielectric layer, the superlattice structure is flipped over and bonded to a second substrate by bonding two bonding layers. After the first substrate is removed and the second substrate is thinned, the superlattice structure is patterned to form a fin-shaped structure to undergo further processes to form C-FET structures. Simulation and experimental results show that the introduction of one or more high-Kappa dielectric layers help spread and dissipate heat generated by C-FET structures.

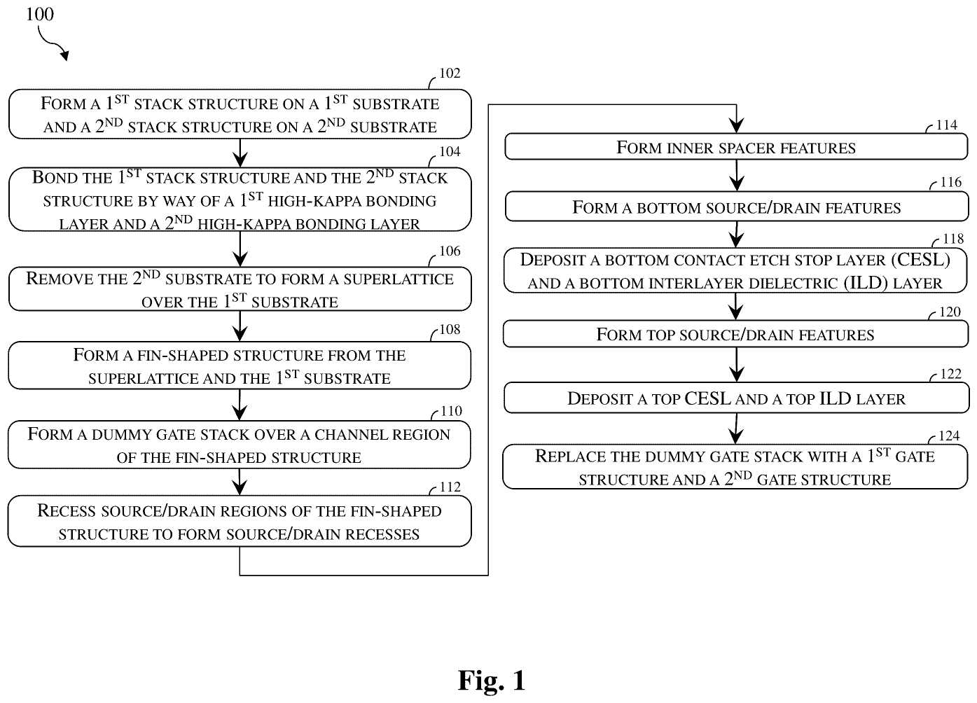

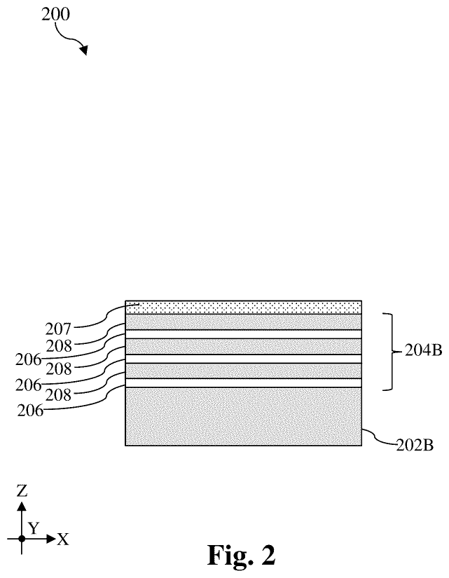

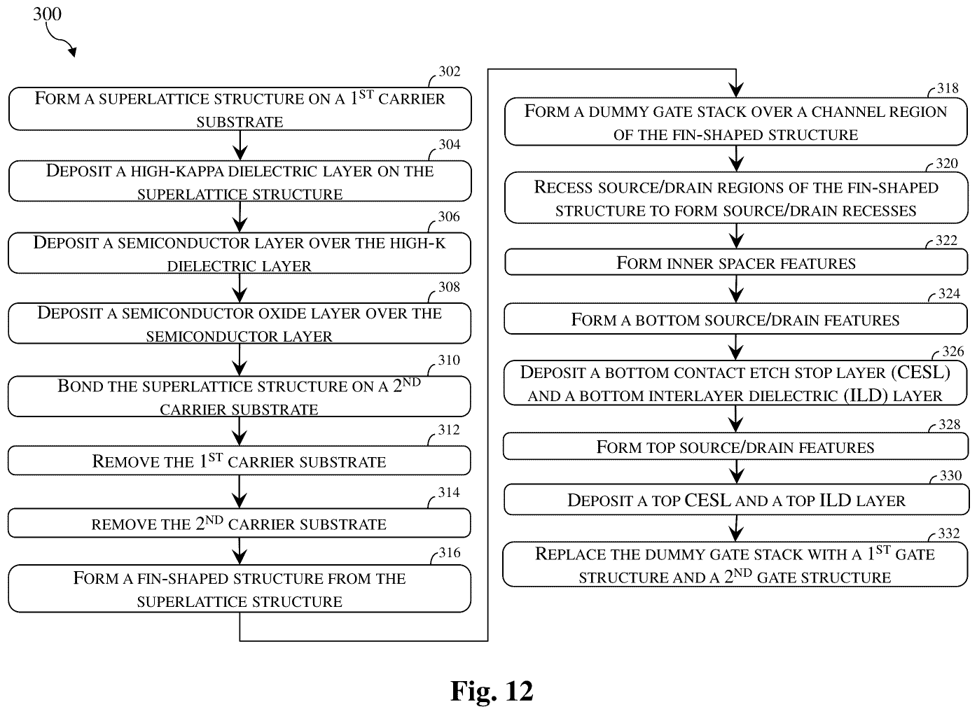

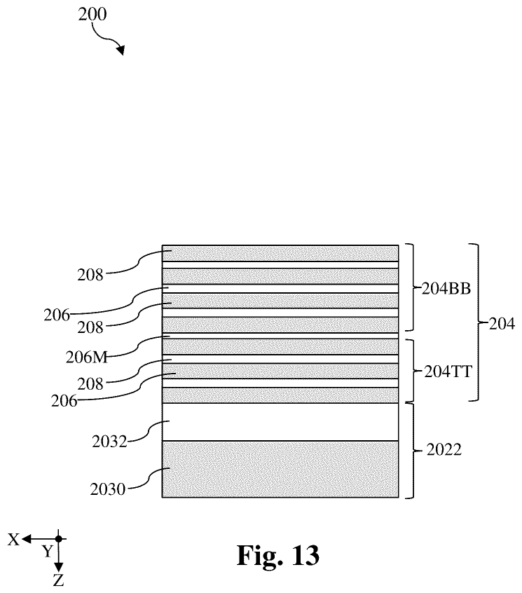

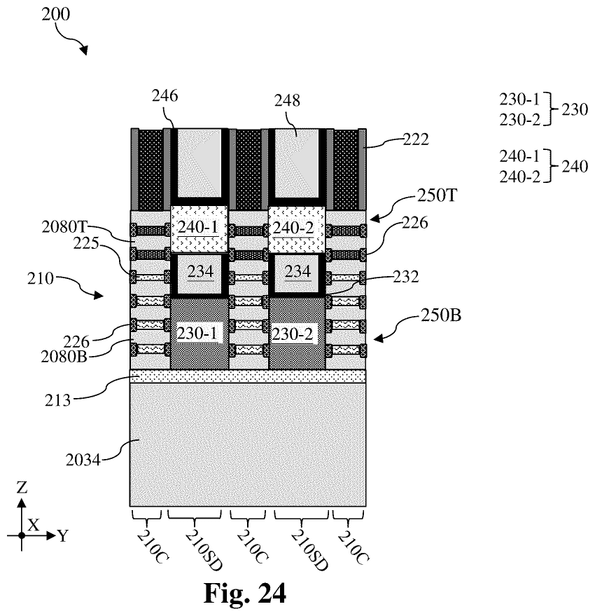

The various aspects of the present disclosure will now be described in more detail with reference to the figures. In that regard, FIG. 1 and FIG. 12 are flowcharts illustrating methods 100 and 300 for forming a semiconductor device according to various aspects of the present disclosure. Methods 100 and 300 are merely examples and are not intended to limit the present disclosure to what is explicitly illustrated in method 100 or method 300. Additional steps may be provided before, during and after method 100 or method 300, and some steps described can be replaced, eliminated, or moved around for additional embodiments of the method. Not all steps are described herein in detail for reasons of simplicity. Method 100 is described below in conjunction with FIGS. 2-11, which are fragmentary cross-sectional views of a workpiece 200 at different stages of fabrication according to embodiments of method 100. Method 300 is described below in conjunction with FIGS. 13-24, which are fragmentary cross-sectional views of a workpiece 200 at different stages of fabrication according to embodiments of method 300. Because the workpiece 200 will be fabricated into a semiconductor device 200 upon conclusion of the fabrication processes, the workpiece 200 may be referred to as a semiconductor device 200 as the context requires. Additionally, throughout the present application and across different embodiments, like reference numerals denote like features with similar structures and compositions, unless otherwise excepted. Source/drain region(s) may refer to a source or a drain, individually or collectively, dependent upon the context.

Method 100 in FIG. 1 uses two high-Kappa dielectric layers as bonding layers to bond two semiconductor stack structures to form a compound superlattice structure that includes two high-Kappa dielectric layers between a bottom stack and a top stack. The compound superlattice structure undergoes further process steps of method 100 to form a C-FET structure.

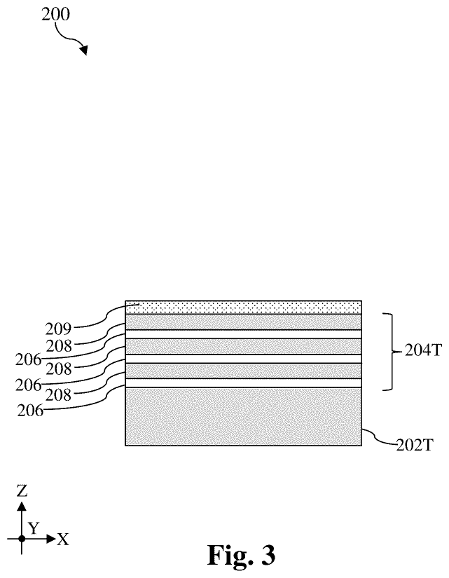

Referring to FIGS. 1, 2 and 3, method 100 includes a block 102 where a first stack structure 204B is formed on a first substrate 202B and a second stack structure 204T is formed a second substrate 202T. Each of the first substrate 202B in FIG. 2 and the second substrate 202T in FIG. 3 may be a silicon (Si) substrate. In some other embodiments, each of the first substrate 202B and the second substrate 202T may include other semiconductors such as germanium (Ge), silicon germanium (SiGe), or a III-V semiconductor material. Example III-V semiconductor materials may include gallium arsenide (GaAs), indium phosphide (InP), gallium phosphide (GaP), gallium nitride (GaN), gallium arsenide phosphide (GaAsP), aluminum indium arsenide (AlInAs), aluminum gallium arsenide (AlGaAs), gallium indium phosphide (GaInP), and indium gallium arsenide (InGaAs). Each of the first substrate 202B and the second substrate 202T may also include an insulating layer, such as a silicon oxide layer, to have a silicon-on-insulator (SOI) structure. Although not explicitly shown in the figures, the first substrate 202B may include an n-type well region and a p-type well region for fabrication of transistors of different conductivity types. When present, each of the n-type well and the p-type well is formed in the first substrate 202B and includes a doping profile. An n-type well may include a doping profile of an n-type dopant, such as phosphorus (P) or arsenic (As). A p-type well may include a doping profile of a p-type dopant, such as boron (B). The doping in the n-type well and the p-type well may be formed using ion implantation or thermal diffusion and may be considered portions of the first substrate 202B. In one embodiment, the first substrate 202B and the second substrate 202T shares the same composition.

Each of the first stack structure 204B and the second stack structure 204T includes a plurality of channel layers 208 interleaved by a plurality of sacrificial layers 206. The channel layers 208 and the sacrificial layers 206 may have different semiconductor compositions. In some implementations, the channel layers 208 are formed of silicon (Si) and sacrificial layers 206 are formed of silicon germanium (SiGe). In these implementations, the additional germanium content in the sacrificial layers 206 allow selective removal or recess of the sacrificial layers 206 without substantial damages to the channel layers 208. The sacrificial layers 206 and the channel layers 208 are deposited alternatingly, one-after-another, to form the first stack structure 204B or the second stack structure 204T. It is noted that each of the first stack structure 204B in FIG. 2 and the second stack structure 204T in FIG. 3 includes two (2) layers of the channel layers 208 interleaved by three (3) layers of sacrificial layers 206, which is for illustrative purposes only and not intended to be limiting beyond what is specifically recited in the claims. It can be appreciated that any number of the channel layers 208 can be included in each of the first stack structure 204B and the second stack structure 204T. The number of layers depends on the desired number of channels members for the top GAA transistor and the bottom GAA transistor. In some embodiments, the number of the channel layers 208 in each of the first stack structure 204B and the second stack structure 204T may be between 2 and 5.

The channel layers 208 in the first stack structure 204B will provide channel members of a bottom GAA transistor, and the channel layers 208 in the second stack structure 204T will provide channel members of a top GAA transistor. The term “channel member(s)” is used herein to designate any material portion for channel(s) in a transistor with nanoscale dimensions, and having an elongate shape, regardless of the cross-sectional shape of this portion. Channel members may come in forms of nanowires, nanosheet, or other nanostructures and may have cross-sections that are circular, oval, race-track shaped, rectangular, or square. Each of the channel layers 208 and the sacrificial layers 206 in the first stack structure 204B and the second stack structure 204T are deposited one over another using vapor-phase epitaxy (VPE), ultra-high vacuum chemical vapor deposition (UHV-CVD), molecular beam epitaxy (MBE), and/or other suitable epitaxy deposition processes.

After formation of the first stack structure 204B, a first bonding layer 207 is deposited over the first stack structure 204B and a second bonding layer 209 is deposited over the second stack structure 204T. In order to function properly as heat sink, the first bonding layer 207 and the second bonding layer 209 include high-Kappa dielectric material. In some embodiments, the first bonding layer 207 and the second bonding layer 209 may include metal nitride, metal oxide, silicon carbide, graphene, or diamond. Example metal nitride includes aluminum nitride, boron nitride, or a suitable metal nitride that is not electrically conductive. Example metal oxide includes yttrium oxide (Y₂O₃), yttrium aluminum garnet (YAG), aluminum oxide, beryllium oxide, or a suitable non-conductive metal oxide. Diamond as used herein may refer to diamond or diamond like carbon (DLC) coating. While commonly used in semiconductor fabrication, silicon nitride and silicon oxide have much lower thermal conductivity than silicon. Thermal conductivity of silicon is about 156 W/mK while that of silicon oxide is between 1 W/mK and 2 W/mK and that of silicon nitride is about 30 W/mK. Similarly, low-Kappa dielectric materials such as silicon oxynitride has thermal conductivity between about 1 W/mK and about 2 W/mk. The foregoing high-Kappa dielectric materials have thermal conductivity similar to or greater than that of silicon. For example, the thermal conductivity of aluminum nitride is about 320 W/mK, the thermal conductivity of silicon carbide is about 120 W/mK, the thermal conductivity of boron nitride is about 751 W/mK, and the thermal conductivity of a diamond like carbon coating is between about 400 and 1000 W/mK. In some embodiments, the first bonding layer 207 and the second bonding layer 209 may be deposited on the first stack structure 204B and the second stack structure 204T using atomic layer deposition (ALD), plasma enhanced chemical vapor deposition (PECVD), CVD, physical vapor deposition (PVD). To improve quality of the first bonding layer 207 and the second bonding layer 209, an anneal process may be performed after their deposition. In some instances, the anneal process may include an anneal temperature between about 400° C. and about 600° C. While a higher anneal temperature may be desirable in terms of effect of densification, annealing at a temperature greater than 600° C. may cause interdiffusion of germanium atoms in the sacrificial layers 206. To prevent wafer warpage, compositions and formation processes for the first bonding layer 207 and the second bonding layer 209 may be substantially the same. This ensures that both the first bonding layer 207 and the second bonding layer 209 have the same coefficient of thermal expansion (CTE). Each of the first bonding layer 207 and the second bonding layer 209 may have a thickness between about 0.5 nm and about 50 nm. In some embodiments, the first bonding layer 207 and the second bonding layer 209 share the same thickness. In some other embodiments, the first bonding layer 207 and the second bonding layer 209 may have different thicknesses.

In some embodiments represented in FIGS. 2 and 3, the first bonding layer 207 is deposited on a topmost channel layer 208 of the first stack structure 204B and the second bonding layer 209 is directly deposited on a topmost channel layer 208 of the second stack structure 204T. The present disclosure is not so limited. Depending of the design, the first bonding layer 207 or the second bonding layer 209 may also be deposited directly on a topmost sacrificial layer 206. It is also possible that the first stack structure 204B and the second stack structure 204T have different numbers of channel layers 208 or sacrificial layers 206 such that one of the first bonding layer 207 is deposited on a channel layer 208 while the second bonding layer 209 is deposited on a sacrificial layer 206, or vice versa. In some embodiments, in the interest of efficient modulization, the first stack structure 204B and the first bonding layer 207 are identical to the second stack structure 204T and the second bonding layer 209. That way, manufacturers do not need to fabricate two different kinds of stack structures.

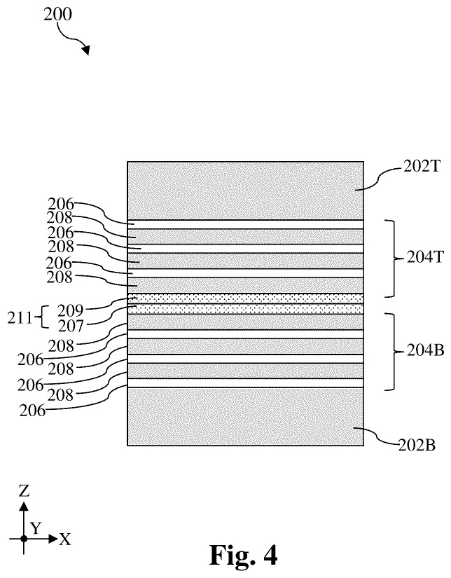

Referring to FIGS. 1 and 4, method 100 includes a block 104 where the second stack structure 204T is bonded over the first stack structure 204B. As shown in FIG. 4, the second stack structure 204T is bonded to the first stack structure 204B by directly bonding the second bonding layer 209 to the first bonding layer 207. That is, the second stack structure 204T and the second bonding layer 209, as a whole, are turned upside down for the bonding at block 104. To bond the first bonding layer 207 and the second bonding layer 209, their exposed surfaces are first treated with a nitrogen (N₂) plasma, an oxygen (O₂) plasma, or an argon (Ar) plasma to introduce surface dangling bonds (e.g., hydroxyl bond). After the treatment, surfaces of the first bonding layer 207 and the second bonding layer 209 are cleaned with deionized (DI) water. In some alternative embodiments, before the plasma treatment, the first bonding layer 207 and the second bonding layer 209 may be optionally cleaned to remove organic and metallic contaminants. In an example process, a mixture of ammonium hydroxide and hydrogen peroxide (SC1) and/or a mixture of hydrochloric acid and hydrogen peroxide (SC2) may be used to clean surfaces of the first bonding layer 207 and the second bonding layer 209. The mixture of ammonium hydroxide and hydrogen peroxide (SC1) may remove organic contaminants. The mixture of hydrochloric acid and hydrogen peroxide (SC2) may remove metallic contaminants. After the plasma treatment, the second bonding layer 209 is brought to direct contact with the first bonding layer 207. An anneal is performed to promote the van der Waals force bonding of the second bonding layer 209 to the first bonding layer 207. Because no active regions or gate structures have been formed on the first substrate 202B and the second substrate 202T, the bonding at block 104 only requires aligning the first substrate 202B and the second substrate 202T. For example, when both the first substrate 202B and the second substrate 202T are wafers with notches to indicate crystalline orientation, bonding at block 104 only requires aligning the two wafers as long as their notches. While the first bonding layer 207 and the second bonding layer 209 are bonded together at block 104, an observable interface may exist at between them, indicating that they are once two separate layers.

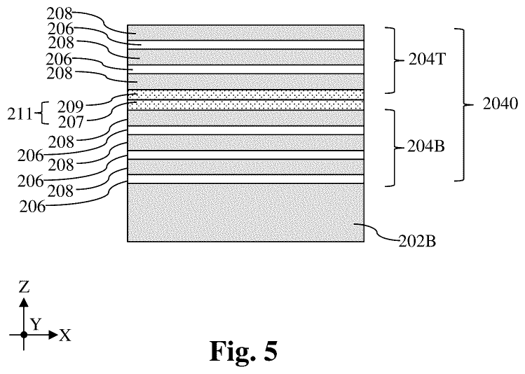

Referring to FIGS. 1 and 5, method 100 includes a block 106 where the second substrate 202T is removed to form a superlattice 2040. After the second stack structure 204T is bonded to the first stack structure 204B by way of the first bonding layer 207 and the second bonding layer 209, the second substrate 202T (shown in FIG. 4) is removed by a combination of mechanical grinding and chemical mechanical polishing (CMP). In one embodiment, the second substrate 202T is first mechanically ground to a suitable thickness and then the thinned second substrate 202T is removed by a CMP process. After the removal of the second substrate 202T, a superlattice 2040 is formed on the first substrate 202B. As shown in FIG. 5, the superlattice 2040 includes the first stack structure 204B, the first bonding layer 207, the second bonding layer 209, and the second stack structure 204T. For ease of references, the first bonding layer 207 and the second bonding layer 209 may be referred to as bonding layers 211. Because the superlattice 2040 includes two stack structures bonded together by the bonding layers 211, it may also be referred to as a composite stack 2040 or an assembled stack 2040.

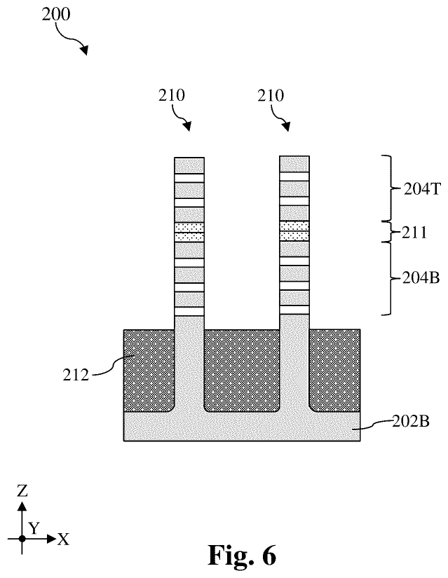

Referring to FIGS. 1 and 6, method 100 includes a block 108 where a fin-shaped structure 210 is formed from the superlattice 2040 and a portion of the first substrate 202B. For patterning purposes, a hard mask layer may be deposited over the superlattice 2040. The hard mask layer may be a single layer or a multilayer. In one example, the hard mask layer includes a silicon oxide layer and a silicon nitride layer over the silicon oxide layer. As shown in FIG. 6, the fin-shaped structure 210 extends vertically along the Z direction from the first substrate 202B and extends lengthwise along the Y direction. The fin-shaped structure 210 may be patterned using suitable processes including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a material layer is formed over a substrate and patterned using a photolithography process. Spacers are formed alongside the patterned material layer using a self-aligned process. The material layer is then removed, and the remaining spacers, or mandrels, may then be used as an etch mask to etch the superlattice 2040 and the first substrate 202B to form the fin-shaped structure 210. The etching process may include dry etching, wet etching, reactive ion etching (RIE), and/or other suitable processes.

After the fin-shaped structure 210 is formed, an isolation feature 212 is formed around the fin-shaped structure 210 to separate the fin-shaped structure 210 from an adjacent fin-shaped structure 210. The isolation feature 212 may also be referred to as a shallow trench isolation (STI) feature 212. In an example process, a dielectric material for the isolation feature is deposited over the workpiece 200, including the fin-shaped structure 210, using CVD, subatmospheric CVD (SACVD), flowable CVD, spin-on coating, and/or other suitable process. Then the deposited dielectric material is planarized and recessed to form the isolation feature 212. As shown in FIG. 6, the fin-shaped structure 210 rises above the isolation feature 212. The dielectric material for the isolation feature 212 may include silicon oxide, silicon oxynitride, fluorine-doped silicate glass (FSG), a low-k dielectric, combinations thereof, and/or other suitable materials. In the embodiments represented in FIG. 6, a base portion of the fin-shaped structure 210 that is formed from the first substrate 202B is buried in the isolation feature 212. This base portion may also be referred to as a base fin. In some embodiments represented in FIG. 6, the portion of the fin-shaped structure 210 that is formed from the superlattice 2040 rises above a top surface of the isolation feature 212.

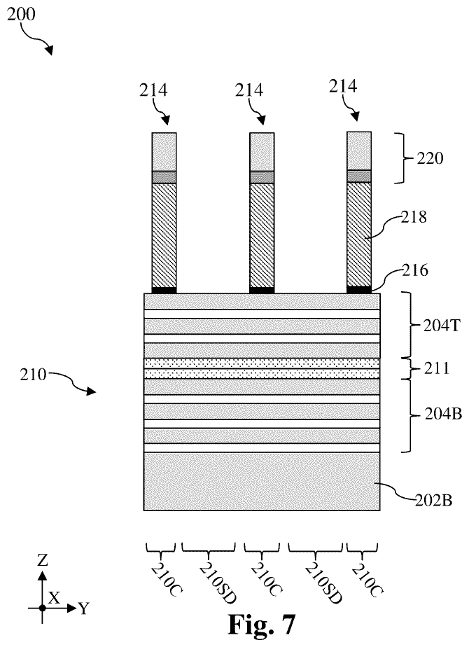

Referring to FIGS. 1 and 7, method 100 includes a block 110 where a dummy gate stack 214 is formed over a channel region 210C of the fin-shaped structure 210. In some embodiments, a gate replacement process (or gate-last process) is adopted where the dummy gate stack 214 serves as a placeholder for a functional gate structure. Other processes and configuration are possible. To form the dummy gate stack 214, a dummy dielectric layer 216, a dummy gate electrode layer 218, and a gate-top hard mask layer 220 are deposited over the workpiece 200. The deposition of these layers may include use of low-pressure CVD (LPCVD), CVD, plasma-enhanced CVD (PECVD), PVD, ALD, thermal oxidation, e-beam evaporation, or other suitable deposition techniques, or combinations thereof. The dummy dielectric layer 216 may include silicon oxide, the dummy gate electrode layer 218 may include polysilicon, and the gate-top hard mask layer 220 may be a multi-layer that includes silicon oxide and silicon nitride. Using photolithography and etching processes, the gate-top hard mask layer 220 is patterned. The photolithography process may include photoresist coating (e.g., spin-on coating), soft baking, mask aligning, exposure, post-exposure baking, photoresist developing, rinsing, drying (e.g., spin-drying and/or hard baking), other suitable lithography techniques, and/or combinations thereof. The etching process may include dry etching (e.g., RIE etching), wet etching, and/or other etching methods. Like the fin-shaped structures 210, the dummy gate stack 214 may also be patterned using double-patterning or multiple-patterning techniques. Thereafter, using the patterned gate-top hard mask 220 as the etch mask, the dummy dielectric layer 216 and the dummy gate electrode layer 218 are then etched to form the dummy gate stack 214. The dummy gate stack 214 extends lengthwise along the X direction to wrap over the fin-shaped structure 210 and lands on the isolation feature 212. The portion of the fin-shaped structure 210 underlying the dummy gate stack 214 defines a channel region 210C. The channel region 210C and the dummy gate stack 214 also define source/drain regions 210SD that are not vertically overlapped by the dummy gate stack 214. The channel region 210C is disposed between two source/drain regions 210SD along the Y direction.

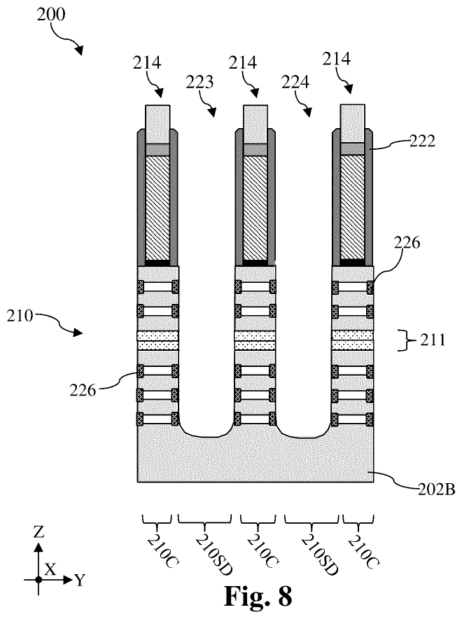

Referring to FIGS. 1 and 8, method 100 includes a block 112 where source/drain regions 210SD of the fin-shaped structure 210 are recessed to form a first source/drain recess 223 and a second source/drain recess 224. Operations at block 112 may include formation of at least one gate spacer layer 222 over the sidewalls of the dummy gate stack 214 before the source/drain regions 210SD are recessed. In some embodiments, the formation of the at least one gate spacer layer 222 includes deposition of one or more dielectric layers over the workpiece 200. In an example process, the one or more dielectric layers are conformally deposited using CVD. SACVD, or ALD. The one or more dielectric layers may include silicon oxide, silicon nitride, silicon carbide, silicon oxynitride, silicon carbonitride, silicon oxycarbide, silicon oxycarbonitride, and/or combinations thereof. After the deposition of the at least one gate spacer layer 222, the workpiece 200 is etched in an anisotropic etch process to form the first source/drain recess 223 and the second source/drain recess 224. The etch process at block 112 may be a dry etch process or a suitable etch process. An example dry etch process may implement an oxygen-containing gas, hydrogen, a fluorine-containing gas (e.g., CF₄, SF₆, NF₃, CH₂F₂, CHF₃, and/or C₂F₆), a chlorine-containing gas (e.g., Cl₂, CHCl₃, CCl₄, and/or BCl₃), a bromine-containing gas (e.g., HBr and/or CHBr₃), an iodine-containing gas, other suitable gases and/or plasmas, and/or combinations thereof. After operations at block 112, sidewalls of the sacrificial layers 206 and the channel layers 208 in the channel regions 210C are exposed in the first source/drain recess 223 and the second source/drain recess 224. Due to their elongated shapes, the first source/drain recess 223 may also be referred to as the first source/drain trench 223 and the second source/drain recess 224 may also be referred to as the second source/drain trench 224.

Referring to FIGS. 1 and 8, method 100 includes a block 114 where inner spacer features 226 are formed. At block 114, the sacrificial layers 206 exposed in the first source/drain recess 223 and the second source/drain recess 224 are selectively and partially recessed to form inner spacer recesses, while the exposed channel layers 208, the exposed first bonding layer 207 and the exposed second bonding layer 209 are substantially unetched. In an embodiment where the channel layers 208 consist essentially of silicon (Si) and sacrificial layers 206 consist essentially of silicon germanium (SiGe), the selective and partial recess of the sacrificial layers 206 may include a SiGe oxidation process followed by a SiGe oxide removal. In that embodiments, the SiGe oxidation process may include use of ozone (O₃). In some other embodiments, the selective recess may be a selective isotropic etching process (e.g., a selective dry etching process or a selective wet etching process), and the extent at which the sacrificial layers 206 are recessed is controlled by duration of the etching process. The selective dry etching process may include use of one or more fluorine-based etchants, such as fluorine gas or hydrofluorocarbons. The selective wet etching process may include use of hydrogen fluoride (HF) or ammonium hydroxide (NH₄OH). After the formation of the inner spacer recesses, an inner spacer material layer is deposited over the workpiece 200, including in the inner spacer recesses. The inner spacer material layer may include silicon oxide, silicon nitride, silicon oxycarbide, silicon oxycarbonitride, silicon carbonitride, metal nitride, or a suitable dielectric material. The deposited inner spacer material layer is then etched back to remove excess inner spacer material layer over the gate spacer layer and sidewalls of the channel layers 208, thereby forming the inner spacer features 226 as shown in FIG. 8. In some embodiments, the etch back process at block 114 may be a dry etch process that includes use of an oxygen-containing gas, hydrogen, nitrogen, a fluorine-containing gas (e.g., NF₃, CF₄, SF₆, CH₂F₂, CHF₃, and/or C₂F₆), a chlorine-containing gas (e.g., Cl₂, CHCl₃, CCl₄, and/or BCl₃), a bromine-containing gas (e.g., HBr and/or CHBr₃), an iodine-containing gas (e.g., CF₃I), other suitable gases and/or plasmas, and/or combinations thereof. It is noted that at block 114, the first bonding layer 207 and the second bonding layer 209, though exposed in the first source/drain recess 223 and the second source/drain recess 224, are substantially unetched and are not replaced with the inner spacer material.

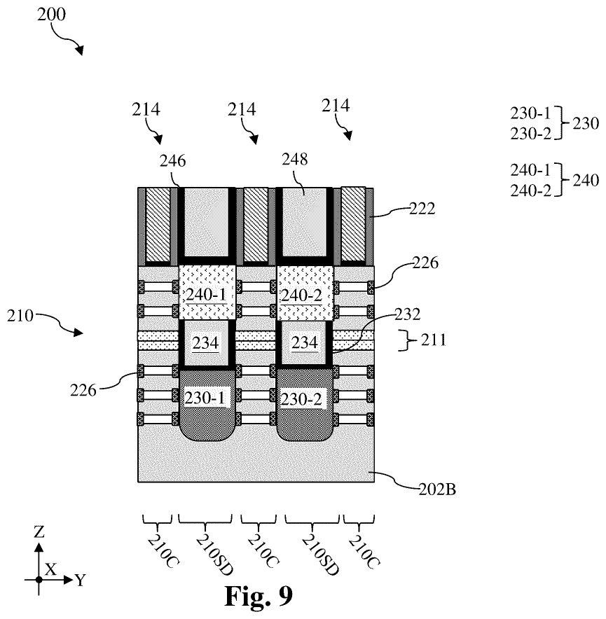

Referring to FIGS. 1 and 9, method 100 includes a block 116 where a first bottom source/drain feature 230-1 and a second bottom source/drain features 230-2 are formed over the first source/drain recess 223 and the second source/drain recess 224, respectively. For ease of reference, the first bottom source/drain feature 230-1 and the second bottom source/drain feature 230-2 may be collectively referred to as bottom source/drain features 230. Referring to FIG. 9, the bottom source/drain features 230 may be formed using an epitaxial process, such as VPE, UHV-CVD, MBE, and/or other suitable processes. The epitaxial growth process may use gaseous and/or liquid precursors, which interact with semiconductor surfaces. The epitaxial growth of bottom source/drain features 230 may take place from both the top surface of first substrate 202B and the exposed sidewalls of the bottom channel layers 208. As illustrated in FIG. 9, the deposited bottom source/drain features 230 are in physical contact with (or adjoining) the channel layers 208 formed from the first stack structure 204B. Although the epitaxial growth of bottom source/drain features 230 is less likely to take place on surfaces of the inner spacer features 226, overgrowth of the bottom source/drain features 230 allow the bottom source/drain features 230 to merge over the inner spacer features 226. Depending on the design, the bottom source/drain features 230 may be n-type or p-type. In the depicted embodiments, the bottom source/drain features 230 are p-type source/drain features and may include silicon germanium (SiGe) doped with a p-type dopant, such as boron (B). In some alternative embodiments, the bottom source/drain features 230 may be n-type source/drain features and may include silicon (Si) doped with phosphorus (P). In these depicted embodiments, the bottom source/drain features 230 include boron doped silicon germanium (SiGe: B).

Referring to FIGS. 1 and 9, method 100 includes a block 118 where a bottom contact etch stop layer (CESL) 232 and a bottom interlayer dielectric (ILD) layer 234 are deposited. The bottom CESL 232 may include silicon nitride, silicon oxynitride, and/or other materials known in the art. The bottom ILD layer 234 may include materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. In some embodiments, the bottom CESL 232 is first conformally deposited on the workpiece 200 by CVD, ALD, plasma-enhanced chemical vapor deposition (PECVD) process and/or other suitable deposition or oxidation processes and the bottom ILD layer 234 is deposited over the bottom CESL 232 by spin-on coating, FCVD. CVD, or other suitable deposition technique. In some embodiments, after formation of the bottom ILD layer 234, the workpiece 200 may be annealed to improve integrity of the bottom ILD layer 234. As shown in FIG. 9, the bottom CESL 232 and the bottom ILD layer 234 are etched back to exposed sidewalls of the channel layers 208 formed from the second stack structure 204T. The bottom CESL 232 is in direct contact with top surfaces of the bottom source/drain features 230 and sidewalls of the first bonding layer 207 and the second bonding layer 209. Additionally, the bottom CESL 232 is in direct contact with sidewalls of a channel layer 208 formed from the first stack structure 204B and a channel layer 208 formed from the second stack structure 204T. The bottom ILD layer 234 is spaced apart from top the surfaces of the bottom source/drain features 230 and sidewalls of the first bonding layer 207 and the second bonding layer 209 by the bottom CESL 232. As shown in FIG. 9, the bottom CESL 232 is in direct contact with sidewalls of the bonding layers 211, which includes the first bonding layer 207 and the second bonding layer 209.

Referring to FIGS. 1 and 9, method 100 includes a block 120 where a first top source/drain feature 240-1 and a second top source/drain features 240-2 are formed. For ease of reference, the first top source/drain feature 240-1 and the second top source/drain feature 240-2 may be collectively referred to as top source/drain features 240. The top source/drain features 240 may be formed using an epitaxial process, such as VPE, UHV-CVD, MBE, and/or other suitable processes. The epitaxial growth process may use gaseous and/or liquid precursors, which interact with composition of the channel layers 208 formed from the second stack structures 204T. The epitaxial growth of top source/drain features 240 may take place from the exposed sidewalls of the channel layers 208 formed from the second stack structures 204T. The deposited top source/drain features 240 are in physical contact with (or adjoining) the channel layers 208 formed from the second stack structures 204T. Depending on the design, the top source/drain features 240 may be n-type or p-type. In the depicted embodiments, the top source/drain features 240 are n-type source/drain features and may include silicon (Si) doped with an n-type dopant, such as phosphorus (P). In these depicted embodiments, the top source/drain features 240 may include phosphorus doped silicon (Si: P). In some alternative embodiments, the top source/drain features 240 are p-type source/drain features and may include boron-doped silicon germanium (SiGe: B).

Referring to FIGS. 1 and 9, method 100 includes a block 122 where a top CESL 246 and a top ILD layer 248 are deposited over the first top source/drain feature 240-1 and second top source/drain features 240-2. The top CESL 246 may include silicon nitride, silicon oxynitride, and/or other materials known in the art and may be formed by CVD. ALD, plasma-enhanced chemical vapor deposition (PECVD) process and/or other suitable deposition or oxidation processes. In some embodiments, the top CESL 246 is first conformally deposited on the workpiece 200 and the ILD layer 248 is deposited over the top CESL 246 by spin-on coating, FCVD. CVD, or other suitable deposition technique. The top ILD layer 248 may include materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. In some embodiments, after formation of the top ILD layer 248, the workpiece 200 may be annealed to improve integrity of the top ILD layer 248. To remove excess materials and to expose top surfaces of the dummy gate stacks 214, a planarization process, such a chemical mechanical polishing (CMP) process may be performed. The top CESL 246 is in direct contact with top surfaces of the top source/drain features 240 and sidewalls of the at least one gate spacer layer 222. The top ILD layer 248 is spaced apart from top surfaces of the top source/drain features 240 and sidewalls of the at least one gate spacer layer 222 by the top CESL 246.

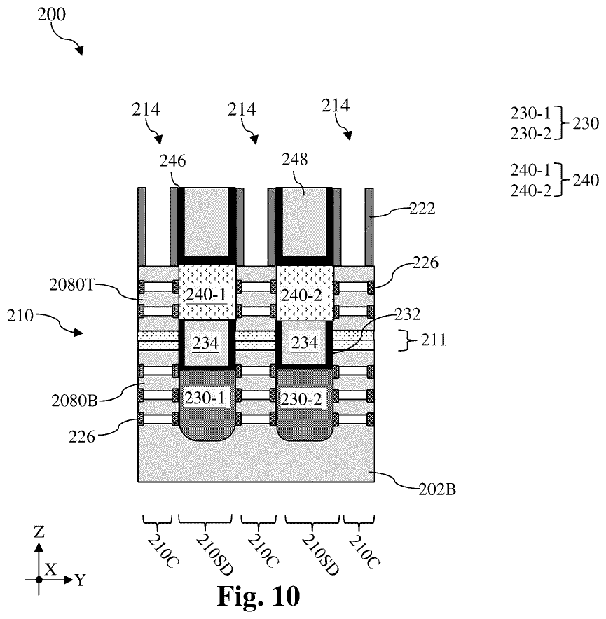

Referring to FIGS. 1, 10 and 11, method 100 includes a block 124 where the dummy gate stack 214 is replaced with a first gate structure 250B and a second gate structure 250T. Operations at block 124 may include removal of the dummy gate stacks 214, release of the channel layers 208 as bottom channel members 2080B and top channel members 2080T, and formation of a first gate structures 250B to wrap around each of the bottom channel members 2080B, and formation of a second gate structure 250T to wrap around each of the top channel members 2080T. The removal of the dummy gate stacks 214 may include one or more etching processes that are selective to the material in the dummy gate stacks 214. For example, the removal of the dummy gate stacks 214 may be performed using as a selective wet etch, a selective dry etch, or a combination thereof. After the removal of the dummy gate stacks 214, sidewalls of the channel layers 208 and sacrificial layers 206 in the channel regions 210C are exposed. Thereafter, the sacrificial layers 206 in the channel regions 210C are selectively removed to release the channel layers 208 formed from the first stack structure 204B as the bottom channel members 2080B and channel layers 208 formed from the second stack structure 204T as the top channel members 2080T, as shown in FIG. 10. In FIG. 10, the bottom channel members 2080B are disposed below the bonding layers 211 and the top channel members 2080T are disposed over the bonding layer 211. Here, because the dimensions of the bottom channel members 2080B or top channel members 2080T are nanoscale, they may also be referred to as nanostructures. The selective removal of the sacrificial layers 206 may be implemented by selective dry etch, selective wet etch, or other selective etch processes. In some embodiments, the selective wet etching includes an APM etch (e.g., ammonia hydroxide-hydrogen peroxide-water mixture). In some other embodiments, the selective removal includes SiGe oxidation followed by a silicon germanium oxide removal. For example, the oxidation may be provided by ozone clean and then silicon germanium oxide removed by an etchant such as NH₄OH.

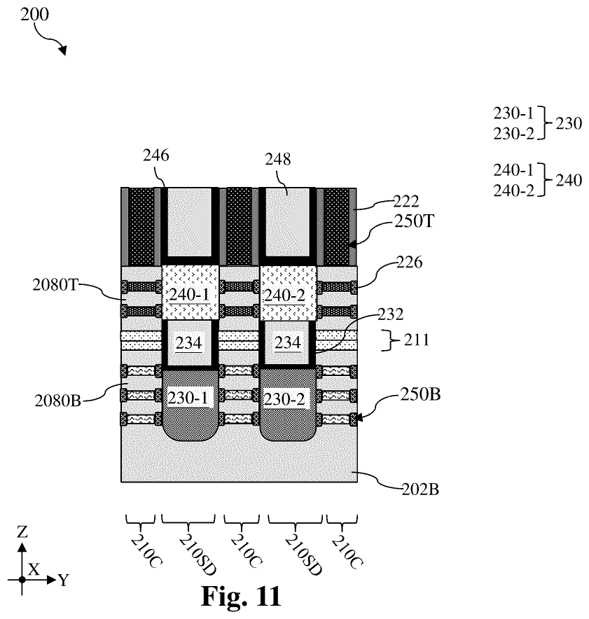

Reference is now made to FIG. 11. With the bottom channel members 2080B and top channel members 2080T released, the first gate structure 250B is deposited to wrap around each of the bottom channel members 2080B, thereby forming a bottom multi-gate transistor. Similarly, the second gate structure 250T is deposited to wrap around each of the top channel members 2080T, thereby forming a top multi-gate transistor. In the depicted embodiments, both the bottom multi-gate transistor and the top multi-gate transistor are GAA transistors that includes vertically stacked channel members 2080. While not explicitly shown in the figures, each of the first gate structure 250B and the second gate structure 250T includes an interfacial layer to interface the channel members 2080, a gate dielectric layer over the interfacial layer, and a work function layer over the gate dielectric layer. In some embodiments, the interfacial layer includes silicon oxide and may be formed in a pre-clean process. An example pre-clean process may include use of RCA SC-1 (ammonia, hydrogen peroxide and water) and/or RCA SC-2 (hydrochloric acid, hydrogen peroxide and water). The gate dielectric layer is then deposited over the interfacial layer using ALD, CVD, and/or other suitable methods. The gate dielectric layer is formed of high-k dielectric materials. As used and described herein, high-k dielectric materials include dielectric materials having a high dielectric constant, for example, greater than that of thermal silicon oxide (˜3.9). The gate dielectric layer may include hafnium oxide. Alternatively, the gate dielectric layer may include other high-k dielectrics, such as titanium oxide (TiO₂), hafnium zirconium oxide (HfZrO), tantalum oxide (Ta₂O₅), hafnium silicon oxide (HfSiO₄), zirconium oxide (ZrO₂), zirconium silicon oxide (ZrSiO₂), lanthanum oxide (La₂O₃), aluminum oxide (Al₂O₃), zirconium oxide (ZrO), yttrium oxide (Y₂O₃), SrTiO₃ (STO), BaTiO₃ (BTO), BaZrO, hafnium lanthanum oxide (HfLaO), lanthanum silicon oxide (LaSiO), aluminum silicon oxide (AlSiO), hafnium tantalum oxide (HfTaO), hafnium titanium oxide (HfTiO), (Ba,Sr)TiO₃ (BST), combinations thereof, or other suitable material. The gate dielectric layer may or may not share the same composition with the first bonding layer 207 and the second bonding layer 209. In the depicted embodiments, the gate dielectric layer does not share the same composition with the first bonding layer 207 and the second bonding layer 209.

After the deposition of the gate dielectric layer, a p-type work function layer may be deposited to form the first gate structure 250B and an n-type work function layer may be deposited to form the second gate structure 250T. The p-type work function layer and the n-type work function layer may include a single layer or alternatively a multi-layer structure, such as various combinations of a metal layer with a selected work function to enhance the device performance (work function metal layer). By way of example, the p-type work function layer may include titanium nitride (TiN), tantalum nitride (TaN), ruthenium (Ru), molybdenum (Mo), aluminum (Al), tungsten nitride (WN), zirconium silicide (ZrSi₂), molybdenum silicide (MoSi₂), tantalum silicide (TaSi₂), nickel silicide (NiSi₂), other p-type work function material, or combinations thereof. The n-type work function layer may include titanium (Ti), aluminum (Al), silver (Ag), manganese (Mn), zirconium (Zr), titanium aluminum (TiAl), titanium aluminum carbide (TiAlC), tantalum carbide (TaC), tantalum carbonitride (TaCN), tantalum silicide nitride (TaSiN), tantalum aluminum (TaAl), tantalum aluminum carbide (TaAlC), titanium aluminum nitride (TiAlN), other n-type work function material, or combinations thereof. Each of the first gate structure 250B and the second gate structure 250T may also include a metal fill to reduce contact resistance. In some instance, the metal fill includes tungsten (W). In the depicted embodiment, the first gate structure 250B includes a p-type work function layer and the second gate structure 250T includes a n-type work function layer.

Method 300 in FIG. 12 forms a superlattice structure on a first substrate and then deposit a high-Kappa dielectric layer on the superlattice structure. A semiconductor layer is then deposited on the high-Kappa dielectric layer. By way of a first bonding layer deposited on the semiconductor layer and a second bonding layer deposited on a second substrate, the superlattice structure is bonded to the second substrate. After the first substrate is removed and the second substrate is thinned. The superlattice structure undergoes further processes to form a C-FET structure. Compared to method 100 where two high-Kappa dielectric layers are introduced between bottom channel members and top channel members, method 300 introduces a high-Kappa dielectric layer below all the channel members.

Referring to FIGS. 12 and 13, method 300 includes a block 302 where a superlattice structure 204 is formed on a first carrier substrate 2022. The first carrier substrate 2022 in FIG. 13 may include a first semiconductor layer 2030 and a second semiconductor layer 2032 over the first semiconductor layer 2030. The second semiconductor layer 2032 may etch faster than the first semiconductor layer 2030 to facilitate etching or polishing end point when the first carrier substrate 2022 is removed. In some embodiments, the first semiconductor layer 2030 may include silicon (Si) and the second semiconductor layer 2032 may include silicon germanium (SiGe). The superlattice structure 204 includes a third stack structure 204TT and a fourth stack structure 204BB. The third stack structure 204TT and the fourth stack structure 204BB are spaced apart from one another by a high-germanium layer 206M, which has a greater germanium content that the other sacrificial layers 206. Each of the third stack structure 204TT and the fourth stack structure 204BB includes a plurality of channel layers 208 interleaved by a plurality of sacrificial layers 206. The channel layers 208 and the sacrificial layers 206 may have different semiconductor compositions. In some implementations, the channel layers 208 are formed of silicon (Si) and sacrificial layers 206 are formed of silicon germanium (SiGe). In these implementations, the additional germanium content in the sacrificial layers 206 allow selective removal or recess of the sacrificial layers 206 without substantial damages to the channel layers 208. The sacrificial layers 206 and the channel layers 208 are deposited alternatingly, one-after-another, to form the third stack structure 204TT and the fourth stack structure 204BB. It is noted that the third stack structure 204TT includes three (3) layers of channel layers 208 interleaved by two (2) layers of sacrificial layers 206 and the fourth stack structure 204BB includes four (4) layers of the channel layers 208 interleaved by three (3) layers of sacrificial layers 206. The third stack structure 204TT and the fourth stack structure 204BB depicted in FIG. 13 are for illustrative purposes only and not intended to be limiting beyond what is specifically recited in the claims. It can be appreciated that any number of the channel layers 208 can be included in each of the first stack structure 204B and the second stack structure 204T. The number of layers depends on the desired number of channels members for the top GAA transistor and the bottom GAA transistor. In some embodiments, the number of the channel layers 208 in each of the third stack structure 204TT and the fourth stack structure 204BB may be between 2 and 5.

The channel layers 208 in the fourth stack structure 204BB will provide channel members of a bottom GAA transistor, and the channel layers 208 in the third stack structure 204TT will provide channel members of a top GAA transistor. The term “channel member(s)” is used herein to designate any material portion for channel(s) in a transistor with nanoscale dimensions, and having an elongate shape, regardless of the cross-sectional shape of this portion. Channel members may come in forms of nanowires, nanosheet, or other nanostructures and may have cross-sections that are circular, oval, race-track shaped, rectangular, or square. Each of the channel layers 208 and the sacrificial layers 206 in the third stack structure 204TT and the fourth stack structure 204BB are deposited one over another using vapor-phase epitaxy (VPE), ultra-high vacuum chemical vapor deposition (UHV-CVD), molecular beam epitaxy (MBE), and/or other suitable epitaxy deposition processes.

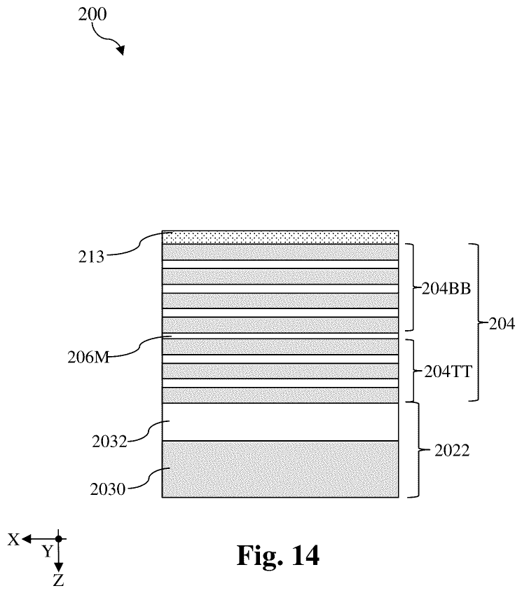

Referring to FIGS. 12 and 14, method 300 includes a block 304 where a high-Kappa dielectric layer 213 is deposited on the superlattice structure 204. After formation of the superlattice structure 204, a high-Kappa dielectric layer 213 is deposited over the superlattice structure 204. In order to function properly as heat sink, the high-Kappa dielectric layer 213 include high-Kappa dielectric material. In some embodiments, the high-Kappa dielectric layer 213 may include metal nitride, metal oxide, silicon carbide, graphene, or diamond. Example metal nitride includes aluminum nitride, boron nitride, or a suitable metal nitride that is not electrically conductive. Example metal oxide includes yttrium oxide (Y₂O₃), yttrium aluminum garnet (YAG), aluminum oxide, beryllium oxide, or a suitable non-conductive metal oxide. Diamond as used herein may refer to diamond or diamond like carbon (DLC) coating. While commonly used in semiconductor fabrication, silicon nitride and silicon oxide have much lower thermal conductivity than silicon. Thermal conductivity of silicon is about 156 W/mK while that of silicon oxide is between 1 W/mK and 2 W/mK and that of silicon nitride is about 30 W/mK. Similarly, low-Kappa dielectric materials such as silicon oxynitride has thermal conductivity between about 1 W/mK and about 2 W/mk. The foregoing high-Kappa dielectric materials have thermal conductivity similar to or greater than that of silicon. For example, the thermal conductivity of aluminum nitride is about 320 W/mK, the thermal conductivity of silicon carbide is about 120 W/mK, the thermal conductivity of boron nitride is about 751 W/mK, and the thermal conductivity of a diamond like carbon coating is between about 400 and 1000 W/mK. In some embodiments, the high-Kappa dielectric layer 213 may be deposited on the superlattice structure 204 using atomic layer deposition (ALD), plasma enhanced chemical vapor deposition (PECVD), CVD, physical vapor deposition (PVD). To improve quality of the superlattice structure 204, an anneal process may be performed after their deposition. In some instances, the anneal process may include an anneal temperature between about 400° C. and about 600° C. While a higher anneal temperature may be desirable in terms of effect of densification, annealing at a temperature greater than 600° C. may cause interdiffusion of germanium atoms in the sacrificial layers 206. The high-Kappa dielectric layer 213 may have a thickness between about 0.5 nm and about 100 nm.

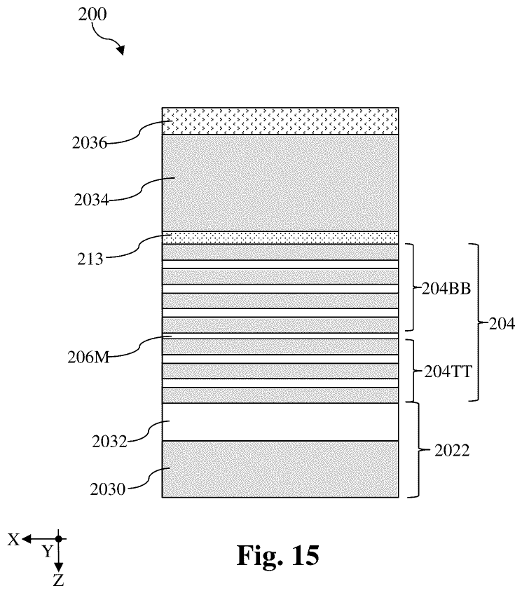

Referring to FIGS. 12 and 15, method 300 includes a block 306 where a semiconductor layer 2034 is deposited on the high-Kappa dielectric layer 213. In some embodiments, the semiconductor layer 2034 is an amorphous silicon (a-Si) layer that is deposited using ALD, PECVD, or CVD. In some implementations, the semiconductor layer 2034 has a thickness between about 50 nm and about 500 nm.

Referring to FIGS. 12 and 15, method 300 includes a block 308 where a first oxide layer 2036 is deposited on the semiconductor layer 2034. In some embodiments, the first oxide layer 2036 includes silicon oxide or silicon oxynitride. The first oxide layer 2036 may be deposited using ALD, PECVD, CVD, or PVD. In some instances, the first oxide layer 2036 may have a thickness between about 0.5 nm and about 50 nm.

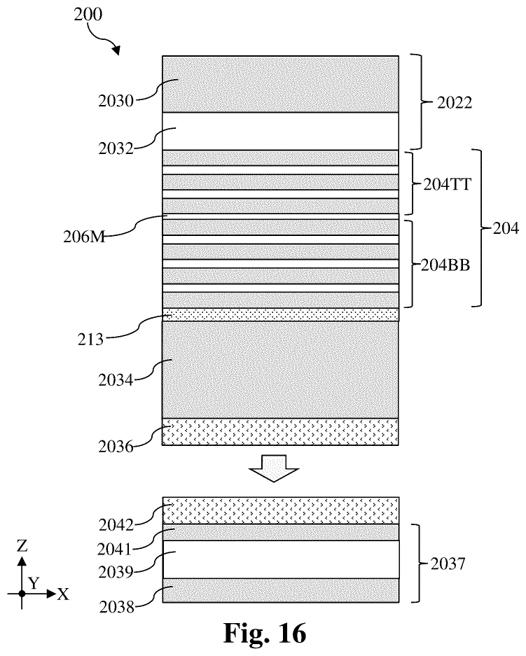

Referring to FIGS. 12 and 16, method 300 includes a block 310 where the superlattice structure 204 is bonded to a second carrier substrate 2037 by bonding the first oxide layer 2036 and a second oxide layer 2042 on the second carrier substrate 2037. In some embodiments, the second carrier substrate 2037 may include a first silicon layer 2038, a silicon germanium layer 2039 disposed on the first silicon layer 2038, and a second silicon layer 2041 disposed on the silicon germanium layer 2039, as shown in FIG. 16. In some alternative embodiments not shown in FIG. 16, the second carrier substrate 2037 may include silicon. To prepare for the subsequent bonding step, a second oxide layer 2042 is deposited over the second carrier substrate 2037. The second oxide layer 2042 may share the same composition and formation processes with the first oxide layer 2036. In some implementations, the second oxide layer 2042 includes silicon oxide or silicon oxynitride and may be deposited using ALD, PECVD, CVD, or PVD. At block 310, the superlattice structure 204, along with the first carrier substrate 2022, is flipped upside down and bonded to the second carrier substrate 2037 by bonding the first oxide layer 2036 and the second oxide layer 2042. To bond the first oxide layer 2036 and the second oxide layer 242, their exposed surfaces are first treated with a nitrogen (N₂) plasma, an oxygen (O₂) plasma, or an argon (Ar) plasma to introduce surface dangling bonds (e.g., hydroxyl bond). After the treatment, surfaces of the first oxide layer 2036 and the second oxide layer 2042 are cleaned with deionized (DI) water. In some alternative embodiments, before the plasma treatment, the first oxide layer 2036 and the second oxide layer 2042 may be optionally cleaned to remove organic and metallic contaminants. In an example process, a mixture of ammonium hydroxide and hydrogen peroxide (SC1) and/or a mixture of hydrochloric acid and hydrogen peroxide (SC2) may be used to clean surfaces of the first oxide layer 2036 and the second oxide layer 2042. The mixture of ammonium hydroxide and hydrogen peroxide (SC1) may remove organic contaminants. The mixture of hydrochloric acid and hydrogen peroxide (SC2) may remove metallic contaminants. After the plasma treatment, the first oxide layer 2036 is brought to direct contact with the second oxide layer 2042. An anneal is performed to promote the van der Waals force bonding of the first oxide layer 2036 and the second oxide layer 2042. While the first oxide layer 2036 and the second oxide layer 2042 are bonded together at block 310, an observable interface may exist between them, indicating that they are once two separate layers.

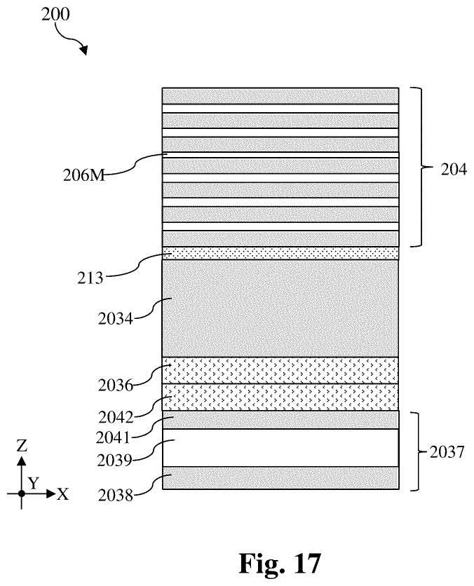

Referring to FIGS. 12 and 17, method 300 includes a block 312 where the first carrier substrate 2022 is removed. After the superlattice structure 204 is bonded to a second carrier substrate 2037 by way of the first oxide layer 2036 and the second oxide layer 2042, the first carrier substrate 2022 (shown in FIG. 16) is removed by a combination of mechanical grinding and chemical mechanical polishing (CMP). In one embodiment, the first carrier substrate 2022 is first mechanically ground to a suitable thickness and then the thinned first carrier substrate 2022 is removed by a CMP process. After the removal of the first carrier substrate 2022, a top surface of the superlattice structure 204 is exposed.

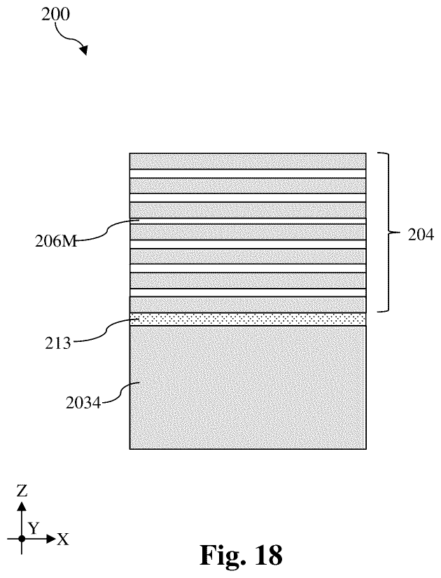

Referring to FIGS. 12 and 18, method 300 includes a block 314 where the second carrier substrate 2037 is removed. After the removal of the first carrier substrate 2022 (shown in FIG. 16), the second carrier substrate 2037 is removed by a combination of mechanical grinding and chemical mechanical polishing (CMP). In one embodiment, the second carrier substrate 2037 is first mechanically ground to a suitable thickness and then the thinned second carrier substrate 2037 is removed by a CMP process. After the removal of the second carrier substrate 2037, the second oxide layer 2042 (shown in FIG. 17) is exposed. In the depicted embodiments, the second oxide layer 2042 and the first oxide layer 2036 are removed by a combination of mechanical grinding and CMP to expose the semiconductor layer 2034.

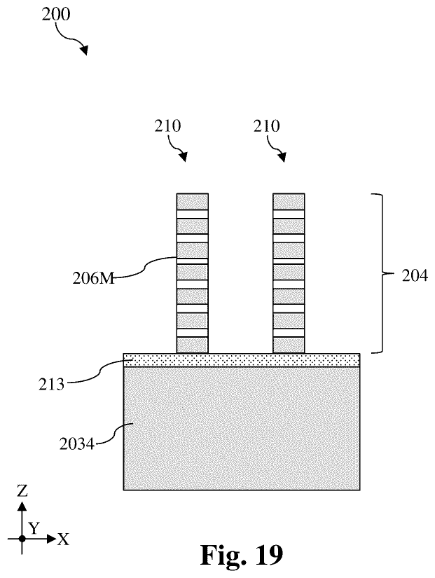

Referring to FIGS. 12 and 19, method 300 includes a block 316 where a fin-shaped structure 210 is formed from the superlattice structure 204. For patterning purposes, a hard mask layer may be deposited over the superlattice structure 204. The hard mask layer may be a single layer or a multilayer. In one example, the hard mask layer includes a silicon oxide layer and a silicon nitride layer over the silicon oxide layer. As shown in FIG. 19, the fin-shaped structure 210 extends vertically along the Z direction from a top surface of the high-Kappa dielectric layer 213 and extends lengthwise along the Y direction. It is noted that the high-Kappa dielectric layer 213 serves as an etch stop layer here and the trenches that defined the fin-shaped structure 210 terminate on or in the high-Kappa dielectric layer 213 and do not extend into the semiconductor layer 2034. The fin-shaped structure 210 may be patterned using suitable processes including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a material layer is formed over a substrate and patterned using a photolithography process. Spacers are formed alongside the patterned material layer using a self-aligned process. The material layer is then removed, and the remaining spacers, or mandrels, may then be used as an etch mask to etch the superlattice structure 204 to form the fin-shaped structure 210. The etching process may include dry etching, wet etching, reactive ion etching (RIE), and/or other suitable processes. Because the fin-shaped structure 210 is disposed on the high-Kappa dielectric layer 213, not on the semiconductor layer 2034, no isolation feature (similar to the isolation feature 212 shown in FIG. 6) is needed or formed.

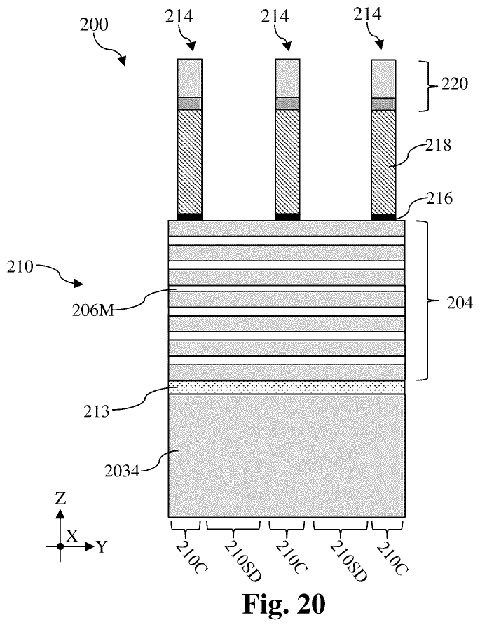

Referring to FIGS. 12 and 20, method 300 includes a block 318 where a dummy gate stack 214 is formed over a channel region 210C of the fin-shaped structure 210. In some embodiments, a gate replacement process (or gate-last process) is adopted where the dummy gate stack 214 serves as a placeholder for a functional gate structure. Other processes and configuration are possible. To form the dummy gate stack 214, a dummy dielectric layer 216, a dummy gate electrode layer 218, and a gate-top hard mask layer 220 are deposited over the workpiece 200. The deposition of these layers may include use of low-pressure CVD (LPCVD), CVD, plasma-enhanced CVD (PECVD), PVD, ALD, thermal oxidation, e-beam evaporation, or other suitable deposition techniques, or combinations thereof. The dummy dielectric layer 216 may include silicon oxide, the dummy gate electrode layer 218 may include polysilicon, and the gate-top hard mask layer 220 may be a multi-layer that includes silicon oxide and silicon nitride. Using photolithography and etching processes, the gate-top hard mask layer 220 is patterned. The photolithography process may include photoresist coating (e.g., spin-on coating), soft baking, mask aligning, exposure, post-exposure baking, photoresist developing, rinsing, drying (e.g., spin-drying and/or hard baking), other suitable lithography techniques, and/or combinations thereof. The etching process may include dry etching (e.g., RIE etching), wet etching, and/or other etching methods. Like the fin-shaped structures 210, the dummy gate stack 214 may also be patterned using double-patterning or multiple-patterning techniques. Thereafter, using the patterned gate-top hard mask 220 as the etch mask, the dummy dielectric layer 216 and the dummy gate electrode layer 218 are then etched to form the dummy gate stack 214. The dummy gate stack 214 extends lengthwise along the X direction to wrap over the fin-shaped structure 210 and lands on the isolation feature 212. The portion of the fin-shaped structure 210 underlying the dummy gate stack 214 defines a channel region 210C. The channel region 210C and the dummy gate stack 214 also define source/drain regions 210SD that are not vertically overlapped by the dummy gate stack 214. The channel region 210C is disposed between two source/drain regions 210SD along the Y direction.

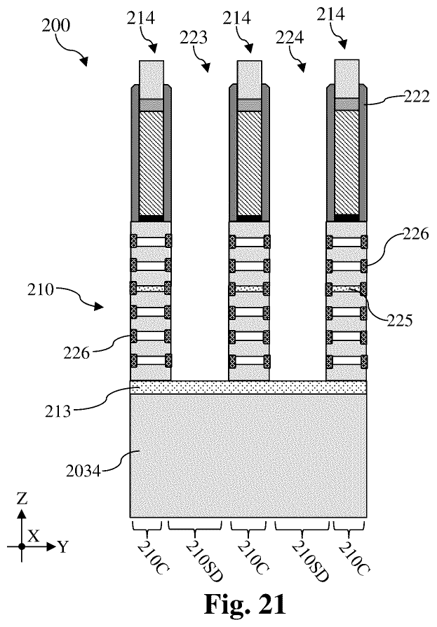

Referring to FIGS. 12 and 21, method 300 includes a block 320 where source/drain regions 210SD of the fin-shaped structure 210 are recessed to form a first source/drain recess 223 and a second source/drain recess 224. Operations at block 320 may include formation of at least one gate spacer layer 222 over the sidewalls of the dummy gate stack 214 before the source/drain regions 210SD are recessed. In some embodiments, the formation of the at least one gate spacer layer 222 includes deposition of one or more dielectric layers over the workpiece 200. In an example process, the one or more dielectric layers are conformally deposited using CVD, SACVD, or ALD. The one or more dielectric layers may include silicon oxide, silicon nitride, silicon carbide, silicon oxynitride, silicon carbonitride, silicon oxycarbide, silicon oxycarbonitride, and/or combinations thereof. After the deposition of the at least one gate spacer layer 222, the workpiece 200 is etched in an anisotropic etch process to form the first source/drain recess 223 and the second source/drain recess 224. The etch process at block 320 may be a dry etch process or a suitable etch process. An example dry etch process may implement an oxygen-containing gas, hydrogen, a fluorine-containing gas (e.g., CF₄, SF₆, NF₃, CH₂F₂, CHF₃, and/or C₂F₆), a chlorine-containing gas (e.g., Cl₂, CHCl₃, CCl₄, and/or BCl₃), a bromine-containing gas (e.g., HBr and/or CHBr₃), an iodine-containing gas, other suitable gases and/or plasmas, and/or combinations thereof. After operations at block 320, sidewalls of the sacrificial layers 206 and the channel layers 208 in the channel regions 210C are exposed in the first source/drain recess 223 and the second source/drain recess 224. Due to their elongated shapes, the first source/drain recess 223 may also be referred to as the first source/drain trench 223 and the second source/drain recess 224 may also be referred to as the second source/drain trench 224. Notably, as shown in FIG. 21, the high-Kappa dielectric layer 213 may once again serve as an etch stop layer to define a bottom surface of the first source/drain recess 223 and the second source/drain recess 224, none of which extends vertically into the semiconductor layer 2034.

Referring to FIGS. 12 and 21, method 300 includes a block 322 where inner spacer features 226 are formed. At block 322, the sacrificial layers 206 exposed in the first source/drain recess 223 and the second source/drain recess 224 are selectively and partially recessed to form inner spacer recesses, while the exposed channel layers 208. The high-germanium layer 206M, due to its greater germanium content, may be substantially or completely removed at block 322, leaving behind a middle gap. In an embodiment where the channel layers 208 consist essentially of silicon (Si) and sacrificial layers 206 consist essentially of silicon germanium (SiGe), the selective and partial recess of the sacrificial layers 206 may include a SiGe oxidation process followed by a SiGe oxide removal. In that embodiments, the SiGe oxidation process may include use of ozone (O₃). In some other embodiments, the selective recess may be a selective isotropic etching process (e.g., a selective dry etching process or a selective wet etching process), and the extent at which the sacrificial layers 206 are recessed is controlled by duration of the etching process. The selective dry etching process may include use of one or more fluorine-based etchants, such as fluorine gas or hydrofluorocarbons. The selective wet etching process may include use of hydrogen fluoride (HF) or ammonium hydroxide (NH₄OH). After the formation of the inner spacer recesses, an inner spacer material layer is deposited over the workpiece 200, including in the inner spacer recesses. The inner spacer material layer may include silicon oxide, silicon nitride, silicon oxycarbide, silicon oxycarbonitride, silicon carbonitride, metal nitride, or a suitable dielectric material. The deposited inner spacer material layer is then etched back to remove excess inner spacer material layer over the gate spacer layer and sidewalls of the channel layers 208, thereby forming the inner spacer features 226 as shown in FIG. 21. In some embodiments, the etch back process at block 322 may be a dry etch process that includes use of an oxygen-containing gas, hydrogen, nitrogen, a fluorine-containing gas (e.g., NF₃, CF₄, SF₆, CH₂F₂, CHF₃, and/or C₂F₆), a chlorine-containing gas (e.g., Cl₂, CHCl₃, CCl₄, and/or BCl₃), a bromine-containing gas (e.g., HBr and/or CHBr₃), an iodine-containing gas (e.g., CF₃I), other suitable gases and/or plasmas, and/or combinations thereof. It is noted that at block 322, the middle gap left behind by the substantial removal of the high-germanium layer 206M may be filled with inner spacer material to form a middle dielectric layer 225. In some alternative embodiments not shown in the figures, the middle dielectric layer 225 may be formed after the sacrificial layers 206 are selectively removed to release the channel layers as channel members. In those alternative embodiments, the high-germanium layer 206M has a smaller thickness and is filled with a gate dielectric layer to form the middle dielectric layer 225. In those embodiments, the middle dielectric layer 225 shares the same composition with the gate dielectric layer.

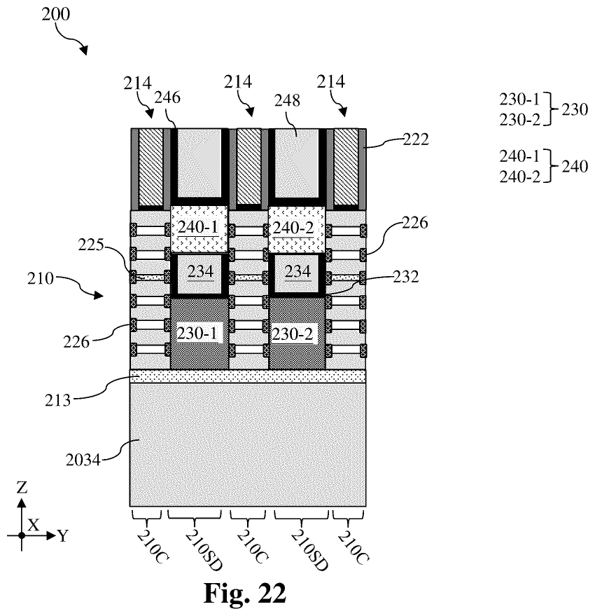

Referring to FIGS. 12 and 22, method 300 includes a block 324 where a first bottom source/drain feature 230-1 and a second bottom source/drain features 230-2 are formed over the first source/drain recess 223 and the second source/drain recess 224, respectively. For ease of reference, the first bottom source/drain feature 230-1 and the second bottom source/drain feature 230-2 may be collectively referred to as bottom source/drain features 230. Referring to FIG. 22, the bottom source/drain features 230 may be formed using an epitaxial process, such as VPE, UHV-CVD, MBE, and/or other suitable processes. The epitaxial growth process may use gaseous and/or liquid precursors, which interact with semiconductor surfaces. The epitaxial growth of bottom source/drain features 230 may take place from the exposed sidewalls of the channel layers 208 below the middle dielectric layer 225. As illustrated in FIG. 22, the deposited bottom source/drain features 230 are in physical contact with (or adjoining) the channel layers 208 below the middle dielectric layer 225. Although the epitaxial growth of bottom source/drain features 230 is less likely to take place on surfaces of the inner spacer features 226, overgrowth of the bottom source/drain features 230 allow the bottom source/drain features 230 to merge over the inner spacer features 226. Depending on the design, the bottom source/drain features 230 may be n-type or p-type. In the depicted embodiments, the bottom source/drain features 230 are p-type source/drain features and may include silicon germanium (SiGe) doped with a p-type dopant, such as boron (B). In some alternative embodiments, the bottom source/drain features 230 may be n-type source/drain features and may include silicon (Si) doped with phosphorus (P). In these depicted embodiments, the bottom source/drain features 230 include boron doped silicon germanium (SiGe: B).

Referring to FIGS. 12 and 22, method 300 includes a block 326 where a bottom contact etch stop layer (CESL) 232 and a bottom interlayer dielectric (ILD) layer 234 are deposited. The bottom CESL 232 may include silicon nitride, silicon oxynitride, and/or other materials known in the art. The bottom ILD layer 234 may include materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. In some embodiments, the bottom CESL 232 is first conformally deposited on the workpiece 200 by CVD. ALD, plasma-enhanced chemical vapor deposition (PECVD) process and/or other suitable deposition or oxidation processes and the bottom ILD layer 234 is deposited over the bottom CESL 232 by spin-on coating, FCVD, CVD, or other suitable deposition technique. In some embodiments, after formation of the bottom ILD layer 234, the workpiece 200 may be annealed to improve integrity of the bottom ILD layer 234. As shown in FIG. 22, the bottom CESL 232 and the bottom ILD layer 234 are etched back to exposed sidewalls of the channel layers 208 above the middle dielectric layer 225. The bottom CESL 232 is in direct contact with top surfaces of the bottom source/drain features 230 and sidewalls of the channel layers 208 immediately above and below the middle dielectric layer 225 as well as sidewalls of inner spacer features 226 that are in contact with the middle dielectric layer 225. The bottom ILD layer 234 is spaced apart from the top surfaces of the bottom source/drain features 230 and the channel layers 208 immediately above and below the middle dielectric layer 225 by the bottom CESL 232.

Referring to FIGS. 12 and 22, method 300 includes a block 328 where a first top source/drain feature 240-1 and a second top source/drain features 240-2 are formed. For ease of reference, the first top source/drain feature 240-1 and the second top source/drain feature 240-2 may be collectively referred to as top source/drain features 240. The top source/drain features 240 may be formed using an epitaxial process, such as VPE, UHV-CVD, MBE, and/or other suitable processes. The epitaxial growth process may use gaseous and/or liquid precursors, which interact with composition of the channel layers 208 over the middle dielectric layer 225. The epitaxial growth of top source/drain features 240 may take place from the exposed sidewalls of the channel layers 208 above the middle dielectric layer 225. The deposited top source/drain features 240 are in physical contact with (or adjoining) the channel layers 208 above the middle dielectric layer 225. Depending on the design, the top source/drain features 240 may be n-type or p-type. In the depicted embodiments, the top source/drain features 240 are n-type source/drain features and may include silicon (Si) doped with an n-type dopant, such as phosphorus (P). In these depicted embodiments, the top source/drain features 240 may include phosphorus doped silicon (Si: P). In some alternative embodiments, the top source/drain features 240 are p-type source/drain features and may include boron-doped silicon germanium (SiGe: B).

Referring to FIGS. 12 and 22, method 300 includes a block 330 where a top CESL 246 and a top ILD layer 248 are deposited over the first top source/drain feature 240-1 and second top source/drain features 240-2. The top CESL 246 may include silicon nitride, silicon oxynitride, and/or other materials known in the art and may be formed by CVD. ALD, plasma-enhanced chemical vapor deposition (PECVD) process and/or other suitable deposition or oxidation processes. In some embodiments, the top CESL 246 is first conformally deposited on the workpiece 200 and the ILD layer 248 is deposited over the top CESL 246 by spin-on coating, FCVD. CVD, or other suitable deposition technique. The top ILD layer 248 may include materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. In some embodiments, after formation of the top ILD layer 248, the workpiece 200 may be annealed to improve integrity of the top ILD layer 248. To remove excess materials and to expose top surfaces of the dummy gate stacks 214, a planarization process, such a chemical mechanical polishing (CMP) process may be performed. The top CESL 246 is in direct contact with top surfaces of the top source/drain features 240 and sidewalls of the at least one gate spacer layer 222. The top ILD layer 248 is spaced apart from top surfaces of the top source/drain features 240 and sidewalls of the at least one gate spacer layer 222 by the top CESL 246.

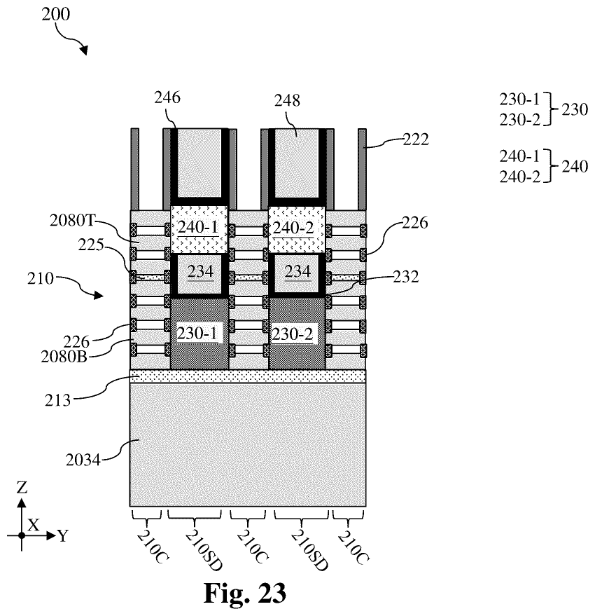

Referring to FIGS. 12, 23 and 24, method 300 includes a block 332 where the dummy gate stack 214 is replaced with a first gate structure 250B and a second gate structure 250T. Operations at block 332 may include removal of the dummy gate stacks 214, release of the channel layers 208 as bottom channel members 2080B and top channel members 2080T, and formation of a first gate structures 250B to wrap around each of the bottom channel members 2080B, and formation of a second gate structure 250T to wrap around each of the top channel members 2080T. The removal of the dummy gate stacks 214 may include one or more etching processes that are selective to the material in the dummy gate stacks 214. For example, the removal of the dummy gate stacks 214 may be performed using as a selective wet etch, a selective dry etch, or a combination thereof. After the removal of the dummy gate stacks 214, sidewalls of the channel layers 208 and sacrificial layers 206 in the channel regions 210C are exposed. Thereafter, the sacrificial layers 206 in the channel regions 210C are selectively removed to release the channel layers 208 below the middle dielectric layer 225 as the bottom channel members 2080B and channel layers 208 above the middle dielectric layer 225 as the top channel members 2080T, as shown in FIG. 23. Here, because the dimensions of the bottom channel members 2080B or top channel members 2080T are nanoscale, they may also be referred to as nanostructures. The selective removal of the sacrificial layers 206 may be implemented by selective dry etch, selective wet etch, or other selective etch processes. In some embodiments, the selective wet etching includes an APM etch (e.g., ammonia hydroxide-hydrogen peroxide-water mixture). In some other embodiments, the selective removal includes SiGe oxidation followed by a silicon germanium oxide removal. For example, the oxidation may be provided by ozone clean and then silicon germanium oxide removed by an etchant such as NH₄OH.

Reference is now made to FIG. 30. With the bottom channel members 2080B and top channel members 2080T released, the first gate structure 250B is deposited to wrap around each of the bottom channel members 2080B, thereby forming a bottom multi-gate transistor. Similarly, the second gate structure 250T is deposited to wrap around each of the top channel members 2080T, thereby forming a top multi-gate transistor. In the depicted embodiments, both the bottom multi-gate transistor and the top multi-gate transistor are GAA transistors that includes vertically stacked channel members 2080. While not explicitly shown in the figures, each of the first gate structure 250B and the second gate structure 250T includes an interfacial layer to interface the channel members 2080, a gate dielectric layer over the interfacial layer, and a work function layer over the gate dielectric layer. In some embodiments, the interfacial layer includes silicon oxide and may be formed in a pre-clean process. An example pre-clean process may include use of RCA SC-1 (ammonia, hydrogen peroxide and water) and/or RCA SC-2 (hydrochloric acid, hydrogen peroxide and water). The gate dielectric layer is then deposited over the interfacial layer using ALD, CVD, and/or other suitable methods. The gate dielectric layer is formed of high-k dielectric materials. As used and described herein, high-k dielectric materials include dielectric materials having a high dielectric constant, for example, greater than that of thermal silicon oxide (˜3.9). The gate dielectric layer may include hafnium oxide. Alternatively, the gate dielectric layer may include other high-k dielectrics, such as titanium oxide (TiO₂), hafnium zirconium oxide (HfZrO), tantalum oxide (Ta₂O₅), hafnium silicon oxide (HfSiO₄), zirconium oxide (ZrO₂), zirconium silicon oxide (ZrSiO₂), lanthanum oxide (La₂O₃), aluminum oxide (Al₂O₃), zirconium oxide (ZrO), yttrium oxide (Y₂O₃), SrTiO₃ (STO), BaTiO₃ (BTO), BaZrO, hafnium lanthanum oxide (HfLaO), lanthanum silicon oxide (LaSiO), aluminum silicon oxide (AlSiO), hafnium tantalum oxide (HfTaO), hafnium titanium oxide (HfTiO), (Ba,Sr)TiO₃ (BST), combinations thereof, or other suitable material. The gate dielectric layer may or may not share the same composition with the high-Kappa dielectric layer 213. In the depicted embodiments, the gate dielectric layer does not share the same composition with the high-Kappa dielectric layer 213.

After the deposition of the gate dielectric layer, a p-type work function layer may be deposited to form the first gate structure 250B and an n-type work function layer may be deposited to form the second gate structure 250T. The p-type work function layer and the n-type work function layer may include a single layer or alternatively a multi-layer structure, such as various combinations of a metal layer with a selected work function to enhance the device performance (work function metal layer). By way of example, the p-type work function layer may include titanium nitride (TiN), tantalum nitride (TaN), ruthenium (Ru), molybdenum (Mo), aluminum (Al), tungsten nitride (WN), zirconium silicide (ZrSi₂), molybdenum silicide (MoSi₂), tantalum silicide (TaSi₂), nickel silicide (NiSi₂), other p-type work function material, or combinations thereof. The n-type work function layer may include titanium (Ti), aluminum (Al), silver (Ag), manganese (Mn), zirconium (Zr), titanium aluminum (TiAl), titanium aluminum carbide (TiAlC), tantalum carbide (TaC), tantalum carbonitride (TaCN), tantalum silicide nitride (TaSiN), tantalum aluminum (TaAl), tantalum aluminum carbide (TaAlC), titanium aluminum nitride (TiAlN), other n-type work function material, or combinations thereof. Each of the first gate structure 250B and the second gate structure 250T may also include a metal fill to reduce contact resistance. In some instance, the metal fill includes tungsten (W). In the depicted embodiment, the first gate structure 250B includes a p-type work function layer and the second gate structure 250T includes a n-type work function layer.

In one exemplary aspect, the present disclosure is directed to a semiconductor structure. The semiconductor structure includes a semiconductor substrate, a high-Kappa dielectric layer disposed on the semiconductor substrate, a first plurality of nanostructures disposed over the high-Kappa dielectric layer, a middle dielectric layer disposed over the first plurality of nanostructures, a second plurality of nanostructures over the middle dielectric layer, a first gate structure wrapping around the first plurality of nanostructures, and a second gate structure wrapping around the second plurality of nanostructures. The high-Kappa dielectric layer includes metal nitride, metal oxide, silicon carbide, graphene, or diamond.

In some embodiments, the metal nitride includes aluminum nitride or boron nitride. In some embodiments, the metal oxide includes yttrium oxide, yttrium aluminum garnet, aluminum oxide, or beryllium oxide. In some instances, the high-Kappa dielectric layer includes a thickness between about 0.5 nm and about 100 nm. In some embodiments, the first plurality of nanostructures are sandwiched between two first source/drain features. In some embodiments, the two first source/drain features include silicon germanium doped with a p-type dopant. In some embodiments, the second plurality of nanostructures are sandwiched between two second source/drain features. In some instances, the two second source/drain features include silicon doped with an n-type dopant. In some embodiments, bottom surfaces of the two second source/drain features and a bottom surface of first plurality of nanostructures are coplanar.

In another exemplary aspect, the present disclosure is directed to a semiconductor structure. The semiconductor structure includes a first bottom source/drain feature and a second bottom source/drain feature disposed over a substrate, a plurality of bottom channel members extending between and in contact with the first bottom source/drain feature and the second bottom source/drain feature, a first bonding layer over the plurality of bottom channel members, a second bonding layer disposed directly on the first bonding layer, a first top source/drain feature disposed directly over the first bottom source/drain feature, a second top source/drain feature disposed directly over the second bottom source/drain feature, and a plurality of top channel members disposed over the second bonding layer and extending between and in contact with the first top source/drain feature and the second top source/drain feature. The first bonding layer and the second bonding layer include metal nitride, metal oxide, silicon carbide, graphene, or diamond.

In some embodiments, the metal nitride includes aluminum nitride or boron nitride. In some implementations, the metal oxide includes yttrium oxide, yttrium aluminum garnet, aluminum oxide, or beryllium oxide. In some embodiments, the semiconductor structure further includes a contact etch stop layer (CESL) disposed over the first bottom source/drain feature and a dielectric layer disposed on the CESL. The CESL is in direct contact with a top surface of the first bottom source/drain feature, a sidewall of the first bonding layer, a sidewall of the second bonding layer, and a bottom surface of the first top source/drain feature. In some embodiments, the dielectric layer is spaced apart from the top surface of the first bottom source/drain feature, the sidewall of the first bonding layer, and the sidewall of the second bonding layer by the CESL. In some instances, the semiconductor structure further includes a plurality of inner spacer features interleaving the plurality of bottom channel members. The plurality of inner spacer features include silicon oxycarbonitride. In some embodiments, the first bottom source/drain feature and the second bottom source/drain feature include silicon germanium and the first top source/drain feature and the second top source/drain feature include silicon and phosphorus.

In yet another exemplary aspect, the present disclosure is directed to a method. The semiconductor structure includes forming a superlattice on a first substrate, the superlattice including a plurality of channel layers interleaved by a plurality of sacrificial layers, depositing a high-Kappa dielectric layer over the superlattice, depositing a semiconductor layer over the high-Kappa dielectric layer, depositing a first bonding layer over the semiconductor layer, depositing a second bonding layer over a second substrate, flipping the superlattice upside down to bond the first bonding layer and the second bonding layer, removing the first substrate, removing the second substrate, patterning the superlattice to form a fin-shaped structure, forming a dummy gate stack over a channel region of the fin-shaped structure, depositing a gate spacer over the fin-shaped structure and the dummy gate stack, and anisotropically recessing source/drain regions of the fin-shaped structure to form source/drain trenches that expose the high-Kappa dielectric layer, forming bottom source/drain features in the source/drain trenches, depositing a first dielectric layer over the bottom source/drain features, forming top source/drain features over the first dielectric layer, depositing a second dielectric layer over the top source/drain features, removing the dummy gate stack, selectively removing the plurality of sacrificial layers in the channel region to release the plurality of channel layers in the channel region as channel members, and forming a first gate structure to wrap around a first subset of the channel members and a second gate structures to wrap around a second subset of the channel members. The high-Kappa dielectric layer includes metal nitride, metal oxide, silicon carbide, graphene, or diamond.

In some embodiments, the metal nitride includes aluminum nitride or boron nitride and the metal oxide includes yttrium oxide, yttrium aluminum garnet, aluminum oxide, or beryllium oxide. In some implementations, the method further includes before the depositing of the bottom source/drain features, selectively and partially recessing the plurality of sacrificial layers to form inner spacer recesses and forming inner spacer features in the inner spacer recesses. In some instances, the plurality of sacrificial layers include a high-germanium sacrificial layer, the selectively and partially recessing includes substantially removing the high-germanium sacrificial layer to form a middle gap, and the forming of the inner spacer features includes forming a middle dielectric layer in the middle gap.

The foregoing outlines features of several embodiments so that those of ordinary skill in the art may better understand the aspects of the present disclosure. Those of ordinary skill in the art should appreciate that they may readily use the present disclosure as a basis for designing or modifying other processes and structures for carrying out the same purposes and/or achieving the same advantages of the embodiments introduced herein. Those of ordinary skill in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
a semiconductor substrate;
a high-Kappa dielectric layer disposed on the semiconductor substrate;
a first plurality of nanostructures disposed over the high-Kappa dielectric layer;
a middle dielectric layer disposed over the first plurality of nanostructures;
a second plurality of nanostructures over the middle dielectric layer;
a first gate structure wrapping around the first plurality of nanostructures; and
a second gate structure wrapping around the second plurality of nanostructures,
wherein the high-Kappa dielectric layer comprises metal nitride, metal oxide, silicon carbide, graphene, or diamond.

2. The semiconductor structure of claim 1, wherein the metal nitride comprises aluminum nitride or boron nitride.

3. The semiconductor structure of claim 1, wherein the metal oxide comprises yttrium oxide, yttrium aluminum garnet, aluminum oxide, or beryllium oxide.

4. The semiconductor structure of claim 1, wherein the high-Kappa dielectric layer comprises a thickness between about 0.5 nm and about 100 nm.

5. The semiconductor structure of claim 1, wherein the first plurality of nanostructures are sandwiched between two first source/drain features.

6. The semiconductor structure of claim 5, wherein the two first source/drain features comprise silicon germanium doped with a p-type dopant.

7. The semiconductor structure of claim 1, wherein the second plurality of nanostructures are sandwiched between two second source/drain features.

8. The semiconductor structure of claim 7, wherein the two second source/drain features comprise silicon doped with an n-type dopant.

9. The semiconductor structure of claim 7, wherein bottom surfaces of the two second source/drain features and a bottom surface of first plurality of nanostructures are coplanar.

10. A semiconductor structure, comprising:
a first bottom source/drain feature and a second bottom source/drain feature disposed over a substrate;
a plurality of bottom channel members extending between and in contact with the first bottom source/drain feature and the second bottom source/drain feature;
a first bonding layer over the plurality of bottom channel members;
a second bonding layer disposed directly on the first bonding layer;
a first top source/drain feature disposed directly over the first bottom source/drain feature;
a second top source/drain feature disposed directly over the second bottom source/drain feature; and
a plurality of top channel members disposed over the second bonding layer and extending between and in contact with the first top source/drain feature and the second top source/drain feature,
wherein the first bonding layer and the second bonding layer comprise metal nitride, metal oxide, silicon carbide, graphene, or diamond.

11. The semiconductor structure of claim 10, wherein the metal nitride comprises aluminum nitride or boron nitride.

12. The semiconductor structure of claim 10, wherein the metal oxide comprises yttrium oxide, yttrium aluminum garnet, aluminum oxide, or beryllium oxide.

13. The semiconductor structure of claim 10, further comprising:
a contact etch stop layer (CESL) disposed over the first bottom source/drain feature; and
a dielectric layer disposed on the CESL,
wherein the CESL is in direct contact with a top surface of the first bottom source/drain feature, a sidewall of the first bonding layer, a sidewall of the second bonding layer, and a bottom surface of the first top source/drain feature.

14. The semiconductor structure of claim 13, wherein the dielectric layer is spaced apart from the top surface of the first bottom source/drain feature, the sidewall of the first bonding layer, and the sidewall of the second bonding layer by the CESL.

15. The semiconductor structure of claim 10, further comprising:
a plurality of inner spacer features interleaving the plurality of bottom channel members,
wherein the plurality of inner spacer features comprise silicon oxycarbonitride.

16. The semiconductor structure of claim 10,
wherein the first bottom source/drain feature and the second bottom source/drain feature comprise silicon germanium,
wherein the first top source/drain feature and the second top source/drain feature comprise silicon and phosphorus.

17. A method, comprising:
forming a superlattice on a first substrate, the superlattice including a plurality of channel layers interleaved by a plurality of sacrificial layers;
depositing a high-Kappa dielectric layer over the superlattice;
depositing a semiconductor layer over the high-Kappa dielectric layer;
depositing a first bonding layer over the semiconductor layer;
depositing a second bonding layer over a second substrate;
flipping the superlattice upside down to bond the first bonding layer and the second bonding layer;
removing the first substrate;
removing the second substrate;
patterning the superlattice to form a fin-shaped structure;
forming a dummy gate stack over a channel region of the fin-shaped structure;
depositing a gate spacer over the fin-shaped structure and the dummy gate stack; and
anisotropically recessing source/drain regions of the fin-shaped structure to form source/drain trenches that expose the high-Kappa dielectric layer;
forming bottom source/drain features in the source/drain trenches;
depositing a first dielectric layer over the bottom source/drain features;
forming top source/drain features over the first dielectric layer;
depositing a second dielectric layer over the top source/drain features;
removing the dummy gate stack;
selectively removing the plurality of sacrificial layers in the channel region to release the plurality of channel layers in the channel region as channel members; and
forming a first gate structure to wrap around a first subset of the channel members and a second gate structures to wrap around a second subset of the channel members,
wherein the high-Kappa dielectric layer comprises metal nitride, metal oxide, silicon carbide, graphene, or diamond.

18. The method of claim 17,
wherein the metal nitride comprises aluminum nitride or boron nitride,
wherein the metal oxide comprises yttrium oxide, yttrium aluminum garnet, aluminum oxide, or beryllium oxide.

19. The method of claim 17, further comprising:
before the depositing of the bottom source/drain features, selectively and partially recessing the plurality of sacrificial layers to form inner spacer recesses; and
forming inner spacer features in the inner spacer recesses.

20. The method of claim 19,
wherein the plurality of sacrificial layers include a high-germanium sacrificial layer,
wherein the selectively and partially recessing comprises substantially removing the high-germanium sacrificial layer to form a middle gap,
wherein the forming of the inner spacer features comprises forming a middle dielectric layer in the middle gap.
